(19) United States
(12) Patent Application Publication
(10) Pub. No.: US 2011/0292619 A1
(43) Pub. Date: Dec. 1, 2011

(54) ELECTRONIC COMPONENT AND METHOD FOR PRODUCING SUCH AN ELECTRONIC COMPONENT

(76) Inventors: Lars Legler, Dorndorf (DE); Norbert Krause, Eisenach (DE); Enrico Schliwa, Gerstungen (DE); Werner Otto, Dankmarshausen (DE)

(21) Appl. No.: 12/812,276

(22) PCT Filed: Dec. 18, 2008
(86) PCT No.: PCT/EP2008/067820

§ 371 Date: Oct. 21, 2010

(30) Foreign Application Priority Data
Jan. 10, 2008 (DE) 102008003790.7

(51) Int. Cl. H05K 7/00; H05K 3/00

(52) U.S. Cl. 361/748; 29/829

(57) ABSTRACT

An electronic component having electrically conductive contacts and a printed circuit board enclosed by a sheathing made from a first plastic, and a method for manufacturing the electronic component. Such electronic components are used in oil pans of a transmission. The electrically conductive contacts are enclosed by a frame made from a second plastic. The first plastic is a duroplastic, and the second one is a thermoplastic. The thermoplastic does not represent a barrier to transmission oil. It is used for shaping the duroplastic, prepositioning the electrically conductive contacts, and preventing mechanical reworking of the duroplastic. No projections such as tabs or flash layers are created.

### FIELD OF THE INVENTION

The present invention relates to an electronic component having electrically conductive contacts and a printed circuit board enclosed by a sheathing made from a first plastic, and a method for manufacturing the electronic component.

### BACKGROUND INFORMATION

Such electronic components are used in oil pans of a transmission. A duroplastic is used to make the plastic sheathing. Duroplastics, also referred to as duromers, are plastics which are no longer moldable after they have cured and are extremely tough. Resistors, integrated circuits, and electrically conductive supply leads are situated on the printed circuit board. The plastic sheathing prevents the resistors, the integrated circuits, and the electrically conductive supply leads from coming into contact with the oil and therefore protects the resistors and integrated circuits situated on the printed circuit board against an electrical short circuit. The electrically conductive contacts protrude from the plastic sheathing and produce an electrically conductive connection of the resistors situated on the printed circuit board and circuits to electronics situated within or outside of the oil pan. The electrically conductive contacts are encapsulated within the oil pan, thus preventing an electrical short circuit.

The electrically conductive contacts designed as contact rails are end products manufactured from stamping grids. A stamping grid is stamped out from a sheet metal part. The stamping grid has the electrically conductive contact rails and connecting pieces that hold the contact rails in position. After the plastic sheathing process, the metallic connecting pieces are removed. This produces metallic chips. If these chips adhere to the contact rails, the oil within the transmission oil pan is contaminated.

The duroplastic mass has a low viscosity and is pressed under pressure into an interior space formed by two mold halves. The printed circuit board and the stamping grid are fixed in this interior space. The extrusion coating of the printed circuit board and of the stamping grid with duroplastic therefore makes it necessary for the mold halves to be sealed in a complex manner at their abutting surfaces. Areas at which the stamping grid emerges from the duroplastic mass are critical in particular. These outlet points coincide with the abutting surface of the mold halves. The outlet points of the stamping grid define the abutting surfaces of the mold halves and conversely. Despite the complex sealing, thin projecting plastic tabs, so-called flash layers, are formed during the plastic sheathing process on the abutting surfaces of the mold halves, in particular on the outlet point of the stamping grid. These plastic tabs are undesired waste products and must be removed after the electronic component is finished. However, if remnants of these plastic tabs remain on the plastic sheathing, or if removed plastic tabs adhere to the contact rails of the electronic component, the oil within the transmission oil pan is contaminated.

The mold halves define a separating plane at their abutting surfaces. The separating plane runs at approximately the center of the electronic component. Venting is problematic due to the separating plane in the center. Air inclusions are formed between the mold and the plastic during the plastic sheathing process and are visible as recesses on one outer surface of the plastic sheathing. These recesses result in damage to the plastic sheathing, so that a permanent electrical insulation of the resistors and the integrated semiconductors is not assured because of these recesses.

### SUMMARY OF THE INVENTION

An object of the exemplary embodiments and/or exemplary methods of the present invention is to provide a simple method and a simple electronic component for operation in an oil pan of a transmission. It should be ensured that the resistors and circuits situated on the printed circuit board are electrically insulated. The oil within the transmission oil pan should not be contaminated by metallic chips and plastic remnants of the electronic component. Air inclusions should be prevented.

These objectives may be achieved by the features described herein. According to the exemplary embodiments and/or exemplary methods of the present invention, the electrically conductive contacts are enclosed by a frame made from a second plastic. The frame made from the second plastic is used for making it possible to manufacture the electronic component more simply. During the sheathing process with the first plastic, the mold halves are at least partially present on the frame made from the second plastic. A direct contact between the mold halves and the stamping grid is avoided. The plastic frame is an outstandingly suitable sealant for the mold halves. Flash layers formed at the outlet points of the stamping grid during the plastic sheathing process are avoided. In addition, the plastic frame is easy to machine. Channels for a gate and for a vent are formed in the frame made from the second plastic. The channel in the frame used for filling the mold halves is referred to as a gate. Venting is feasible when distributed across the entire periphery of the frame on two surfaces of the frame facing away from one another.

The following method steps are used for simplifying the manufacture of the electronic component: a grid having electrically conductive contacts and having connecting pieces is manufactured, the grid is fixed in a frame made from a second plastic, the connecting pieces of the grid are removed, the printed circuit board is inserted into the frame and placed on the electrically conductive contacts of the grid, and the printed circuit board is enclosed in the first plastic.

Advantageously, the frame made from the second plastic frames the printed circuit board. If the entire printed circuit board is framed, the abutting surfaces of the mold halves are separable from one another over their entire periphery using the frame and may be sealed using the frame.

Advantageously, frame surfaces of frame parts face peripheral surfaces of the printed circuit board. The component side of the printed circuit board is equipped with resistors and integrated circuits. An extension perpendicular to the component surface is smaller than an extension parallel to the peripheral surfaces with regard to the entire part made up of the printed circuit board, resistors, and integrated circuits. In this perpendicular direction, the volume of the frame is thus smallest, resulting in a reduction in material.

Advantageously, the frame is at a distance from the printed circuit board. This makes it possible for the printed circuit board to be completely enclosed by the first plastic.

Advantageously, the distance between the frame and the printed circuit board may be defined using the electrically conductive contacts. The electrically conductive contacts are fixed in the frame. End pieces of the electrically conductive contacts are guided through openings of the printed circuit board, so that the printed circuit board is positioned relative to the frame. Advantageously, the second plastic is a thermoplastic. Thermoplastics are plastics which are moldable across a determined temperature range. This process is reversible, meaning that it may be repeated by cooling and reheating to the molten state any number of times. It should be noted that overheating does not cause thermal decomposition of the material. Thermoplastics differ from duroplastics and elastomers in this way. Thermoplastics may be machined in a simple manner; channels may be produced in a simple manner.

The thermoplastic does not represent a barrier to transmission oil; it is used for shaping the duroplastic, for propositioning the stamping grid and for preventing mechanical reworking of the duroplastic. No projections such as tabs or flash layers are created. The electronic component may be used in a harsh environment.

Advantageously, the sheathing made from the first plastic is flush with the frame made from the second plastic. This makes simple and reliable venting possible.

Advantageously, the connecting pieces are situated within and outside of the frame. This makes reliable positioning of the contact rails possible.

Advantageously, the frame has projections. The projections in the form of tabs and nubs are used for centering and positioning the electronic component in a receiving device, for example, an additional enclosing plastic or a metallic receiving device of the transmission oil pan.

For a better understanding of the present invention, an exemplary embodiment is elucidated below with reference to the drawings.

### BRIEF DESCRIPTION OF THE DRAWINGS

FIG. 1 shows a top view of a stamped grid having electrically conductive contacts and connecting pieces.

FIG. 2 shows a side view of the stamped grid having the electrically conductive contacts and connecting pieces.

FIG. 3 shows a top view of the stamped grid freed from the connecting pieces fixed in a plastic frame.

FIG. 4 shows a side view of the stamped grid freed from the connecting pieces fixed in the plastic frame.

FIG. 5 shows a top view of a printed circuit board placed in the frame and on the stamped grid.

FIG. 6 shows a side view of a cross section of the printed circuit board placed in the frame and on the stamped grid.

FIG. 7 shows a top view of an electronic component having a plastic enclosing the printed circuit board.

FIG. 8 shows a side view of the electronic component having the plastic enclosing the printed circuit board.

### DETAILED DESCRIPTION

Similar elements or the same elements in the various figures are denoted by identical reference numerals.

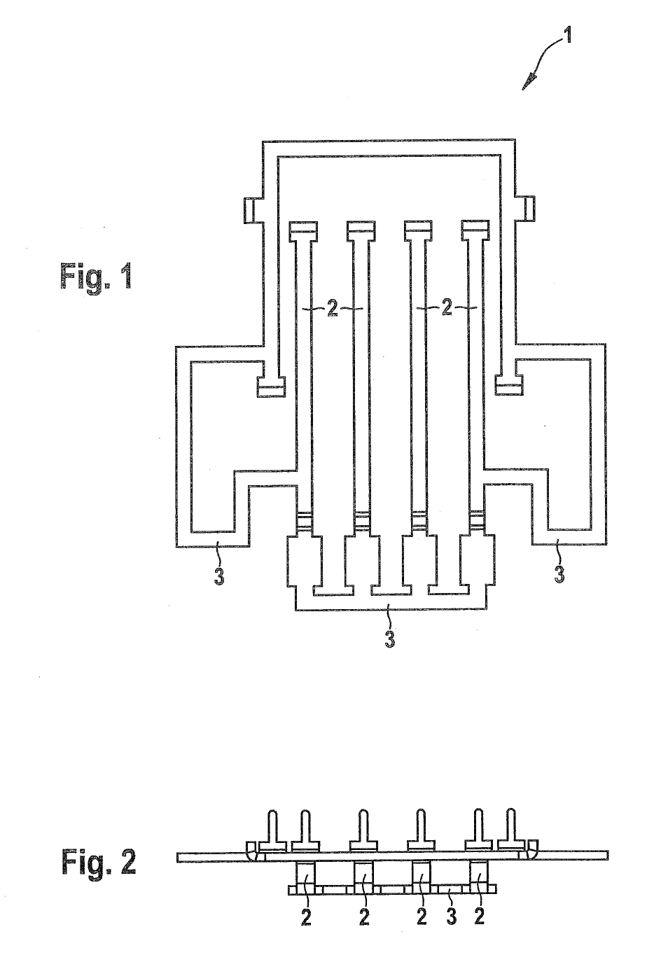

FIGS. 1 and 2 show a part 1 which is stamped from a sheet metal and preformed and which is referred to below as a stamped grid. Stamped grid 1 is manufactured from an electrically conductive material and has electrically conductive contacts 2 in the form of contact rails. Electrically conductive contact rails 2 are connected and held in position using connecting pieces 3.

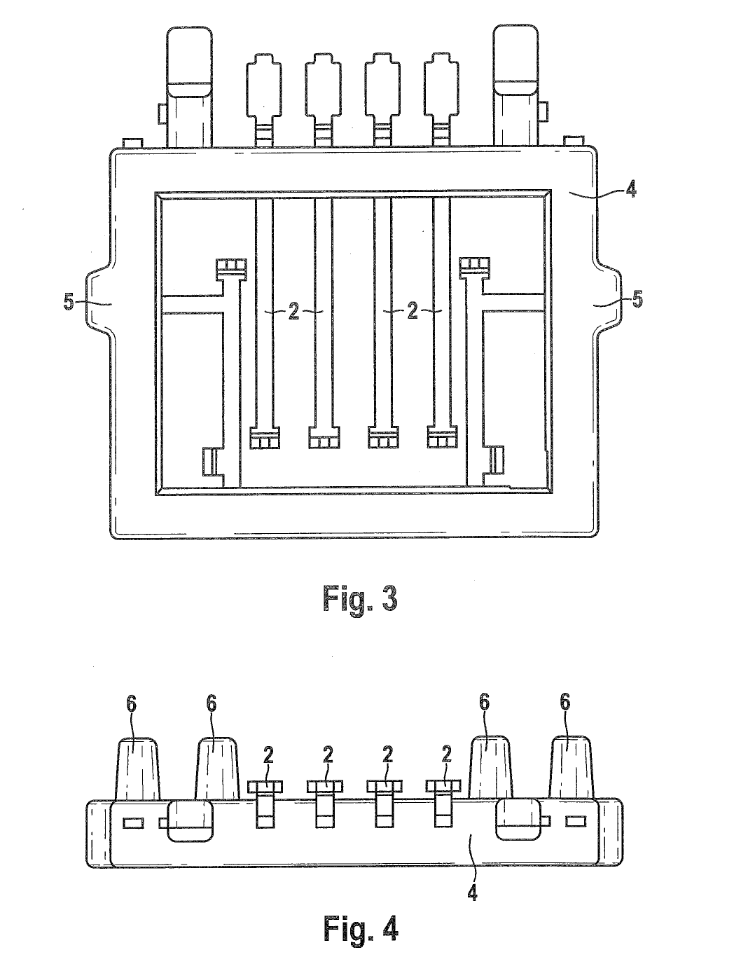

FIGS. 3 and 4 show electrically conductive contact rails 2 fixed in a frame 4 made from a second plastic. Frame 4 encloses the electrically conductive contact rails in areas. Connecting pieces 3 of stamped grid 1 are removed, so that contact rails 2 are electrically insulated from one another and held fixed in position by frame 4. Projections in the form of tabs 5 and nubs 6 are used for centering and fixing frame 4.

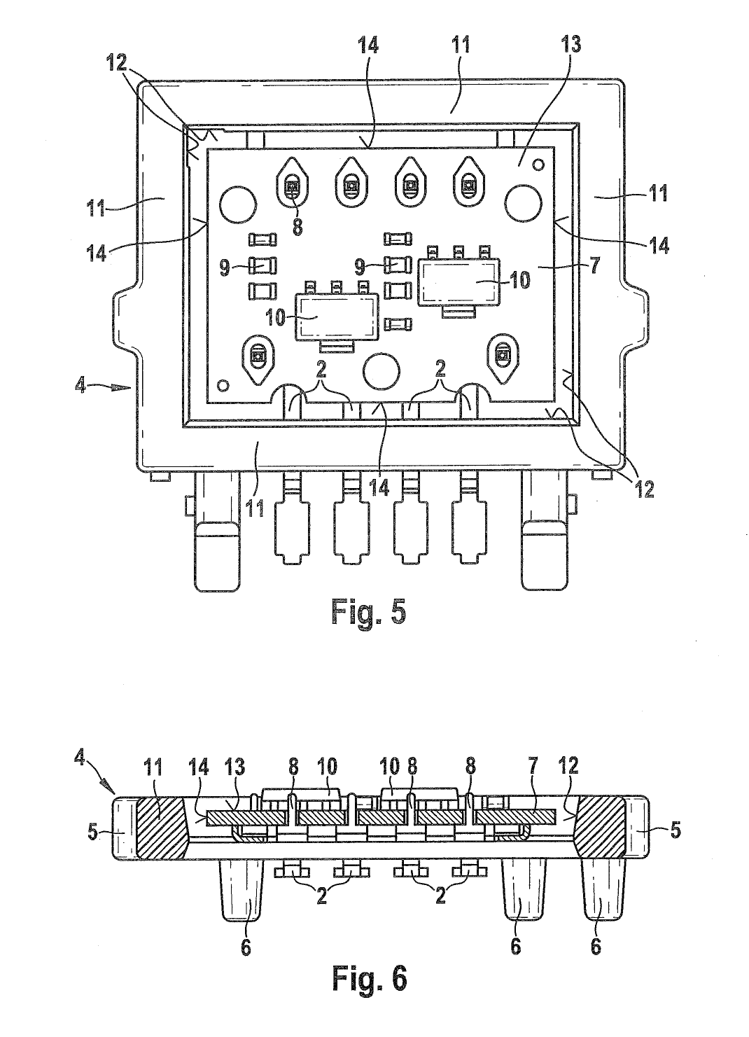

FIGS. 5 and 6 show a printed circuit board 7 placed on electrically conductive contact rails 2. End pieces 8 of electrically conductive contact rails 2 penetrate openings of printed circuit board 7 and are connected electrically conductively to printed conductor tracks on printed circuit board 7. Printed circuit board 7 has resistors 9 and integrated circuits 10. Integrated circuits 10 are Hall elements. Hall elements 10 are used to detect the position of a gear selector lever. Printed circuit board 7 is at a distance from plastic frame 4. Frame 4 has four elongated frame parts 11, two of which are situated parallel to one another in each case. Each frame part 11 has a surface 12 which faces inward. Printed circuit board 7 has a component surface 13, on which are situated resistors 9 and Hall elements 10, and peripheral surfaces 14 which are situated perpendicular to component surface 13. Each frame surface 12 facing inward faces a peripheral surface 14 of printed circuit board 7.

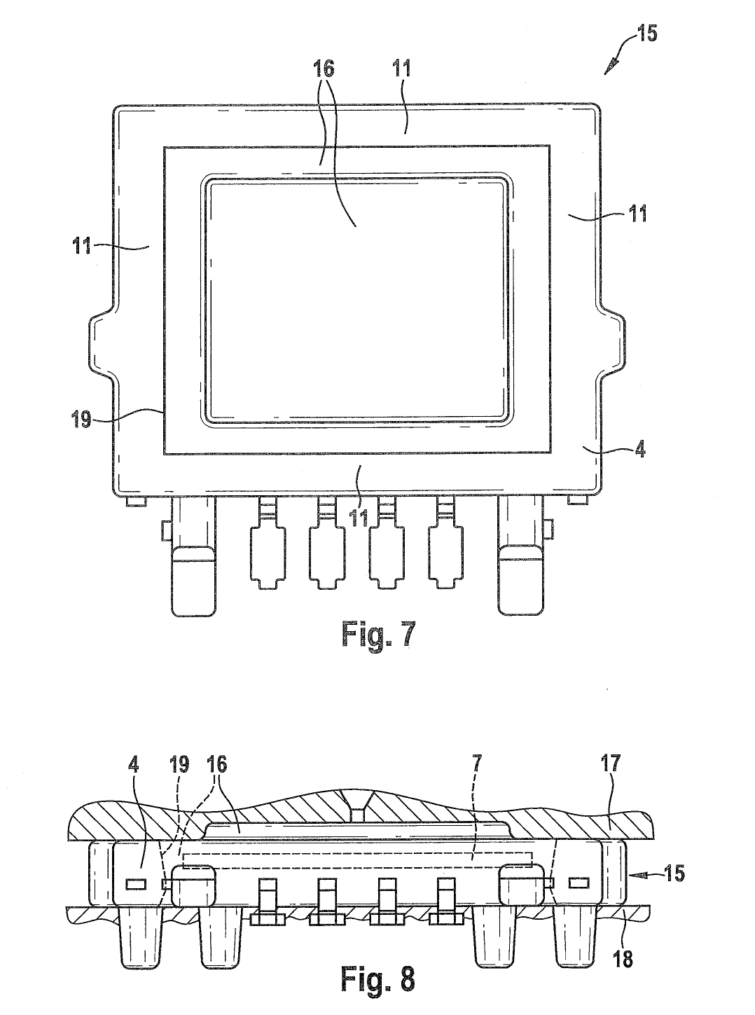

FIGS. 7 and 8 show an electronic component 15 having frame 4 made from the second plastic and sheathing 16 made from the first plastic enclosing printed circuit board 7. The first plastic is a duroplastic; the second plastic is a thermoplastic. The material from which sheathing 16 is manufactured is the first plastic, i.e., a duroplastic. The material from which frame 4 is manufactured is the second plastic, i.e., a thermoplastic. Mold halves 17, 18 of a mold used for enclosing printed circuit board 7 and contact rails 2 lie on frame 4 in such a way that sheathing 16 and frame 4 are flush at a joint 19.

1-10. (canceled)

11. An electronic component, comprising:
electrically conductive contacts;
a printed circuit board which is enclosed by a sheathing made from a first plastic; and
a frame made from a second plastic, wherein the electrically conductive contacts are enclosed by the frame made from the second plastic.

12. The component of claim 11, wherein the frame made from the second plastic frames the printed circuit board.

13. The component of claim 12, wherein frame surfaces of frame parts face peripheral surfaces of the printed circuit board.

14. The component of claim 12, wherein the frame is at a distance from the printed circuit board.

15. The component of claim 14, wherein a distance between the frame and the printed circuit board can be defined using the electrically conductive contacts.

16. The component of claim 11, wherein the second plastic is a thermoplastic.

17. The component of claim 11, wherein the sheathing made from the first plastic is flush with the frame made from the second plastic.

18. The component of claim 11, wherein connecting pieces are situated between the electrically conductive contacts within and outside of the frame.

19. The component of claim 11, wherein the frame has projections.

20. A method for manufacturing an electronic component having electrically conductive contacts and a printed circuit board which is enclosed by a sheathing made from a first plastic, the method comprising:
making a grid having the electrically conductive contacts and having the connecting pieces;
fixing the grid in a frame made from a second plastic;
removing the connecting pieces of the grid;
inserting the printed circuit board into the frame and placed on the electrically conductive contacts of the grid; and
enclosing the printed circuit board by the first plastic.
